(19) United States
(12) Patent Application Publication
(10) Pub. No.: US 2020/0132746 A1
(43) Pub. Date: Apr. 30, 2020

(54) MONITORING SEATING OF A CABLE CONNECTOR(S) WITHIN A SOCKET(S)

(71) Applicant: INTERNATIONAL BUSINESS MACHINES CORPORATION, Armonk, NY (US)

(72) Inventors: Robert K. MULLADY, Highland, NY (US); Matteo COCCHINI, Long Island City, NY (US); Jacob T. PORTER, Highland, NY (US); Budy D. NOTOHARDJONO, Poughkeepsie, NY (US); Robert B. SCHLAK, Hyde Park, NY (US); Kenneth SCEA, Poughkeepsie, NY (US)

(21) Appl. No.: 16/170,220

(22) Filed: Oct. 25, 2018

(51) Int. Cl. G01R 31/04

(52) U.S. Cl. CPC G01R 31/045

(57) ABSTRACT

Monitoring seating of a cable connector within a socket is provided by associating a seating monitor with the socket. The seating monitor includes an actuator and a detector. The actuator is partially exposed within the socket, and is engaged by the connector and moved from a cable unplugged position to a cable plugged position with seating of the connector within the socket. The detector monitors seating of the connector within the socket based on position of the actuator. The detector includes a fixed member fixedly positioned within the detector, and a slidable member slidable relative to the fixed member. The slidable member is coupled to the actuator to slide with movement of the actuator. The detector circuit generates a signal representative of position of the slidable member relative to the fixed member, and thus, representative of position of the cable connector within the socket.

### BACKGROUND

In system networking, such as computer networking, a large number of cables are often plugged within the system network. For instance, a server network can contain tens or even hundreds, or more, cables connecting servers and other components within the network. Depending on the implementation, cables may span between front and back sides of a computer rack, or between computer racks, or across a data center, or even across separate rooms of a facility.

In operation, it is possible for a cable connector to become unseated, or partially unseated or disengaged, from its corresponding socket (or primary contact element), potentially causing errors within the system network. For instance, this condition can lead to interference in the transmission of signals, and can result in an intermittent behavior or a complete failure of a device, subsystem, system, or network.

Various mechanisms can contribute to unseating of a cable connector, such as an operator inadvertently causing a disruption, operational vibration of a connection, poor mechanical engagement and/or mechanical interference with a connection. These issues can arise in a variety of environments, including, for instance, with scalable computing hardware, mainframe computers, similar computer hardware, and even with appliances, or more generally, any cable connected device(s). In certain cases, there have been field and manufacturing issues caused by an unseated cable connector, such as a degraded link condition or a link down condition. The cable connector and associated cables are typically dense for system networking and having substantial mass, which can put added strain on the connections. Sometimes, this strain can cause an unseating, such as a partial unseating, of a connection that is not easy to detect visually. Often, the solution is to reset all of the card and cable connections in a particular link path to address a potential unseating event, which can be time-consuming.

### SUMMARY

Shortcomings of the prior art are overcome and additional advantages are provided through the provision, in one or more aspects, of an apparatus for monitoring seating of a cable connector within a socket. The apparatus includes a seating monitor associated with the socket. The seating monitor includes an actuator and a detector. The actuator is partially exposed within the socket, and is engaged by the cable connector and physically moved from a cable unplugged position to a cable plugged position with seating of the cable connector within the socket. The detector detects and monitors seating of the cable connector within the socket based on position of the actuator. The detector includes a fixed member fixedly positioned within the detector, and a slidable member slidable relative to the fixed member. The slidable member is coupled to the actuator to slide with the actuator's movement between the cable unplugged position and the cable plugged position. The detector further includes a detector circuit to generate a signal representative of position of the slidable member relative to the fixed member, and thus, representative of position of the cable connector within the socket.

In another aspect, an apparatus for monitoring seating of cable connectors within network sockets is provided. The apparatus includes seating monitors associated with the network sockets. Each seating monitor is associated with a respective network socket and includes an actuator and a detector. The actuator is partially exposed within the network socket, and is engaged by a cable connector and physically moved from a cable unplugged position to a cable plugged position with seating of the cable connector within the network socket. The detector detects and monitors seating of the cable connector within the network socket based on position of the actuator. The detector includes a fixed member fixedly positioned within the detector, and a slidable member slidable relative to the fixed member. The slidable member is coupled to the actuator to slide with the actuator's movement between the cable unplugged position and the cable plugged position. The detector includes a detector circuit to generate a signal representative of position of the slidable member relative to the fixed member, and thus, representative of the position of the cable connector within the socket. The apparatus also includes a monitor system coupled to the seating monitors to monitor over time seating of the cable connectors within the network sockets based on the signals generated by the detector circuits of the seating monitors.

In a further aspect, a method of fabricating an apparatus to monitor seating of a cable connector within a socket is provided. The method includes associating a seating monitor with the socket. The associating of the seating monitor includes providing an actuator partially exposed within the socket. The actuator is engaged by the cable connector and physically moved from a cable unplugged position to a cable plugged position with seating of the cable connector within the socket. Associating the seating monitor further includes providing a detector to monitor seating of the cable connector within the socket based on position of the actuator. The detector includes a fixed member fixedly positioned within the detector, and a slidable member slidable relative to the fixed member. The slidable member is coupled to the actuator to slide with movement of the actuator between the cable unplugged position and the cable plugged position. The detector also includes the detector circuit to generate a signal representative of position of the slidable member relative to the fixed member, and thus representative of the position of the cable connector within the socket.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a network with a plurality of cable connections to be monitored, in accordance with one or more aspects of the present invention;

FIG. 2 depicts one embodiment of a cable connector being inserted into a socket with a seating monitor associated therewith to monitor seating of the cable connector within the socket, in accordance with one or more aspects of the present invention;

FIG. 3 is an exploded view of one embodiment of the socket and seating monitor of FIG. 2, in accordance with one or more aspects of the present invention;

FIG. 4A is an exploded view of one embodiment of a slidable card assembly of the seating monitor of FIG. 3, in accordance with one or more aspects of the present invention;

FIG. 4B depicts from an opposite direction the assembly of FIG. 4A, showing capacitor pads and a contact pad on a surface of the slidable card assembly, in accordance with one or more aspects of the present invention;

FIG. 5A depicts one embodiment of a fixed card of the seating monitor of FIG. 3, showing capacitor pads on one surface thereof, as well as an electrical contact arm to electrically engage the contact pad of the slidable card assembly of FIGS. 3-4B, in accordance with one or more aspects of the present invention;

FIG. 5B depicts from an opposite direction one embodiment of the fixed card of FIG. 5A, in accordance with one or more aspects of the present invention;

FIG. 6A is an elevational depiction of a cable connector being seated within a socket with an associated seating monitor, in accordance with one or more aspects of the present invention;

FIG. 6B is an elevational view of the cable connector, socket and seating monitor of FIG. 6A, with the cable connector shown partially unseated from the socket, and with the partial unseating to be detected by the seating monitor, in accordance with one or more aspects of the present invention;

FIG. 7 depicts one embodiment of a detector circuit of a seating monitor for monitoring capacitance between capacitor pads associated with the fixed card and the slidable card of FIGS. 3-6B, in accordance with one or more aspects of the present invention;

FIG. 8 depicts one embodiment of one or more seating monitors providing actuator displacement data to, for instance, a monitor system, in accordance with one or more aspects of the present invention;

FIG. 9 depicts another embodiment of a cable connector being inserted into a socket with a seating monitor associated therewith to monitor seating of the cable connector within the socket, in accordance with one or more aspects of the present invention;

FIG. 10 is an exploded view of one embodiment of the socket and seating monitor of FIG. 9, in accordance with one or more aspects of the present invention;

FIG. 11A is an exploded view of one embodiment of the slidable card assembly of the seating monitor of FIG. 10, in accordance with one or more aspects of the present invention;

FIG. 11B is an elevational view from an opposite direction of the slidable card assembly of FIGS. 11A, showing a conductive spring contact of the seating monitor of FIGS. 10 & 11A, in accordance with one or more aspects of the present invention;

FIG. 12 depicts one embodiment of a fixed card of the seating monitor of FIG. 10, showing electrical contact pads on one surface thereof, in accordance with one or more aspects of the present invention;

FIGS. 13A-13C depict elevational views of the partially assembled seating monitor of FIGS. 10-12, with the actuator and conductive spring contact shown in different positions based on relative seating or unseating of the cable connector within the socket, in accordance with one or more aspects of the present invention;

FIG. 14 depicts another embodiment of a detector circuit for a seating monitor, in accordance with one or more aspects of the present invention;

FIG. 15 depicts one embodiment of a computing system which can implement or facilitate implementing monitoring seating of a cable connector within a socket, in accordance with one or more aspects of the present invention;

FIG. 16 depicts one embodiment of a cloud computing environment, which can implement, or be used in association with one or more aspects of the present invention; and

FIG. 17 depicts one example of abstraction model layers which can facilitate or implement cable connector monitoring processing, in accordance with one or more aspects of the present invention.

### DETAILED DESCRIPTION

Aspects of the present invention and certain features, advantages and details thereof, are explained more fully below with reference to the non-limiting example(s) illustrated in the accompanying drawings. Descriptions of well-known systems, devices, processing techniques, etc., are omitted so as to not unnecessarily obscure the invention in detail. It should be understood, however, that the detailed description in this specific example(s), while indicating aspects of the invention, is given by way of illustration only, and not by way of limitation. Various substitutions, modifications, additions, and/or other arrangements, within the spirit and/or scope of the underlying inventive concepts will be apparent to those skilled in the art from this disclosure. Note also that reference is made below to the drawings, which may not be drawn to scale for ease of understanding, where the same reference numbers used throughout different figures designate the same or similar components. Further, note that numerous inventive aspects and features are disclosed herein, and unless inconsistent, each disclosed aspect or feature is combinable with any other disclosed aspect or feature as desired for a particular application of monitoring seating of one or more cable connectors within one or more sockets of a network.

Certain aspects of the illustrative embodiments may be described below using specific code, designs, architectures, protocols, layouts, schematics, or tools only as examples, and are not limited to the illustrative embodiments. Furthermore, the illustrative embodiments may be described in certain instances using particular software, tools, and data processing environments only as example for clarity of description. The illustrative embodiments can be used in conjunction with other comparable or similarly purposed structures, systems, applications, or architectures. Certain monitor control aspects can be implemented in hardware, software, or a combination thereof

Any advantages listed herein are only examples and are not intended to be limiting to the illustrative embodiments. Additional or different advantages can be realized by specific illustrative embodiments. Furthermore, a particular illustrative embodiment can have some, all, or none of the advantages listed herein.

Networks, such as computer networks, communication networks, power networks, and other networks, as well as many electronic or electrical systems, typically rely on cables to connect product components of the network or system to one another. For instance, within a network, such as a computer network, a large number of cables can be plugged within the network. As noted initially, in operation, it is possible for a cable connector to become unseated, or partially unseated or disengaged, from its corresponding socket (or primary contact element), potentially causing errors within the system network. This condition can lead to interference in the transmission of signals, and can result in an intermittent behavior or a complete failure of a device, subsystem, system, or network.

Various mechanisms can contribute to unseating of a cable connector, such as an operator inadvertently causing a disruption, operational vibration of a connection, poor mechanical engagement, mechanical interference with a connection, etc. These issues can arise in a variety of environments, including, for instance, with data processing centers containing scalable computing hardware, mainframe computers, or other computer hardware, etc., as well as with appliances or other devices. In fact, the unintended unseating of a cable connector can occur with any cable connected device. Depending upon the device, subsystem, system, network, etc., unseating of a cable connector can result in degraded or interrupted operation. For instance, in a data center environment, cable connectors and their associated cables are typically dense for system networking and have substantial mass, which can put added strain on the connections. Sometimes, the strain can cause an unseating, such as a partial unseating, of a connection that is not easy to detect visually.

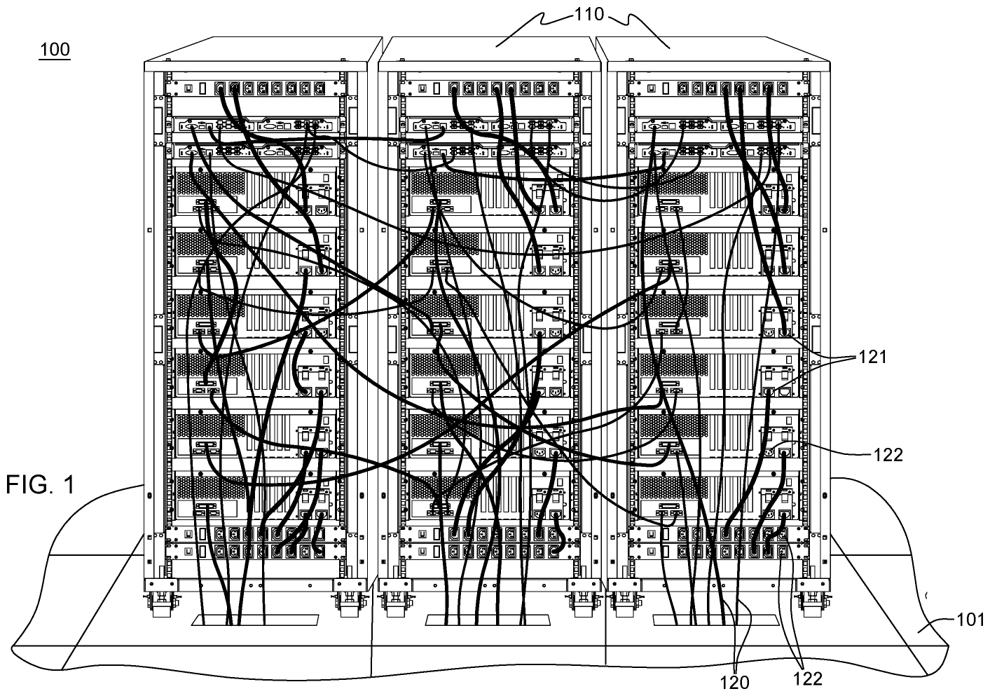

By way of example, FIG. 1 depicts one embodiment of a data center 100 with a plurality of racks 110 of computing equipment. In the example of FIG. 1, data center 100 is a raised floor data center, with the plurality of racks 110 residing on a raised floor 101 of data center 100, by way of example only. Note that FIG. 1 can represent a single network, or multiple interconnected networks. Note also that the phrase “network” is used broadly herein to refer to any computer, communications, power, etc., network or system with product components connect by cables. The product components can be any of a variety of components, with a server rack of a data center being one example of a network, or a portion of a network, having a large number of cables to be plugged to achieve a desired setup configuration or reconfiguration. The cables can be, for instance, power cables, input/output cables, or other communications cables, etc. Typically, a cable can have one or more cable connectors at an end. Note in this regard that the phrases “cable connector” and “connector” are used interchangeably herein. In the example of FIG. 1, multiple cables 120 are shown, each of which has an appropriate cable connector 121 at the ends thereof. Further, the product components of the network are shown to have respective sockets 122 for plugging an appropriate cable into the network to connect the product components of the network in the desired configuration. Note also that although typically having a single first end and a single second end, a “cable” as used herein can include a configuration with multiple first ends and/or multiple second ends, each having associated therewith a cable connector to be plugged in the network (e.g., a Y-cable).

As can be understood from the depiction of FIG. 1, it may be a time-consuming process to determine whether a particular cable connector has become unseated or partially unseated from its respective socket.

Advantageously, disclosed herein are apparatuses and methods to monitor seating of a cable connector within a socket of a network using seating monitors associated with the sockets or receptacles. In one or more embodiments, the seating monitors allow the system to monitor directly a magnitude of seating and/or unseating of a cable connector within the socket. The seating monitors are associated with the sockets, meaning that power is available to conduct system-level monitoring and store any displacement data or unseating information at a central location to determine whether to take an action. In one or more embodiments, the seating monitors can be implemented using capacitive sensors to detect relative displacement, and from the relative displacement data, the monitor system can provide, for instance, a warning when relative displacement or unseating is greater than an allowable value, with displacement data generated being stored for further analyzing and action, if necessary. The seating monitors disclosed herein directly measure, in one or more embodiments, an amount of connector displacement. The aspects disclosed herein can also apply to any type of cable, or cable connector, plugged within a socket, with power connectors being illustrated in the drawings, and described further below by way of example only.

Generally stated, apparatuses and methods are provided herein for monitoring seating of one or more cable connectors within one or more sockets, such as one or more network sockets. The apparatus includes a seating monitor associated with the socket. For instance, the seating monitor can be incorporated, at least in part, into a common socket or receptacle into which the cable connector plugs. The seating monitor includes an actuator partially exposed within the socket, and a detector to detect and monitor seating of the cable connector within the socket based on position of the actuator. The actuator is engaged by the cable connector and physically moved from a cable unplugged position to a cable plugged position with seating of the cable connector within the socket. The detector includes, in one or more embodiments, a fixed member, a slidable member, and a detector circuit. The fixed member, such as a fixed card, is fixedly positioned within the detector. The slidable member, such as a slidable card or slidable card assembly, is slidable relative to the fixed member. The slidable member is coupled to the actuator to slide relative to the fixed member with movement of the actuator between the cable unplugged position and the cable plugged position. The detector further includes a detector circuit to generate a signal representative of position of the slidable member relative to the fixed member, and thus, representative of position of the cable connector within the socket.

Depending upon the seating monitor implementation, the detector circuit could be implemented to generate a signal representative of seated or unseated position of the connector relative to the socket, or could be implemented to provide displacement data indicative of an amount of unseating of the connector cable from the socket for forwarding to, for instance, a monitor system, which monitors displacement change over time, performs trend analysis, and if desired, provides a predictive indication or signal, such as an alarm or service call, that a particular cable connector is about to become unseated from its respective socket.

In one or more implementations, the detector circuit includes a capacitive sensor associated with the fixed member and the slidable member to sense position of the slidable member relative to the fixed member. In such an implementation, the detector circuit generates actuator displacement data from, at least in part, the capacitive sensor, where capacitance sensed by the capacitive sensor varies with position of the slidable member relative to the fixed member. For instance, the capacitive sensor can include one or more first capacitor pads disposed on a first surface of the fixed member, and one or more second capacitor pads disposed on a second surface of the slidable member, where the first surface and the second surface are opposite facing surfaces of the fixed and slidable members.

In one or more specific embodiments, the fixed member is, or includes, a fixed card, and the slidable member is, or includes, a slidable card, where the slidable card is biased towards the fixed card, and spaced from the fixed card via one or more offsets associated with the slidable card and/or the fixed card.

In one or more implementations, the detector circuit includes an electrical contact sensor associated with the fixed member and the slidable member to sense position of the slidable member relative to the fixed member. The detector circuit generates actuator displacement data from, at least in part, the electrical contact sensor, where a signal produced by the detector circuit varies with position of the slidable member relative to the fixed member. For instance, in one or more implementations, the signal can represent a seated or unseated position of the cable connector within the socket.

In one or more embodiments, the electrical contact sensor includes multiple, differently sized contact pads associated with one of the fixed member and the slidable member and a conductive spring contact associated with the other of the fixed member and the slidable member. The conductive spring contact makes electrical connection with one or more different contact pads of the multiple contact pads with changing position of the slidable member relative to the fixed member. For instance, in one or more embodiments, the fixed member is, or includes, a fixed card, and the slidable member is, or includes, a slidable card, and the multiple contact pads are disposed, in one embodiment, on a first surface of the fixed card, and the conductive spring contact is coupled to a second surface of the slidable card, where the first surface and second surface are opposite facing surfaces.

In one or more embodiments, the slidable member is spring-biased in a first direction, and the slidable member moves in a second direction, opposite to the first direction, with movement of the actuator from the cable unplugged position to the cable plugged position.

In certain embodiments, the detector circuit generates an acoustical signal and/or a visual signal based on the signal generated by the detector circuit exceeding a set reference signal representative, for instance, of seating, partial seating and/or unseating of the cable connector within the socket.

In one or more embodiments, a monitor system, such as a cognitive monitoring system, is provided to monitor over time seating of the cable connector(s) within the socket(s), based on the signal(s) generated by the detector circuit. Upon detection of an unseating of a cable connector, at least in part, from a socket, the cognitive monitoring system can perform an action, such as provide an indication that the cable connector should be re-seated within the socket. In one or more embodiments, the cognitive monitoring system can receive signals (or displacement data) from a plurality of seating monitors, for instance, from a plurality of seating monitors within a network. The cognitive monitoring system can be a system-level monitor and storage that receives displacement data or information for analytics, and determines subsequent action. For instance, the monitor system could provide an indication of an unseating, partial unseating, or seating condition.

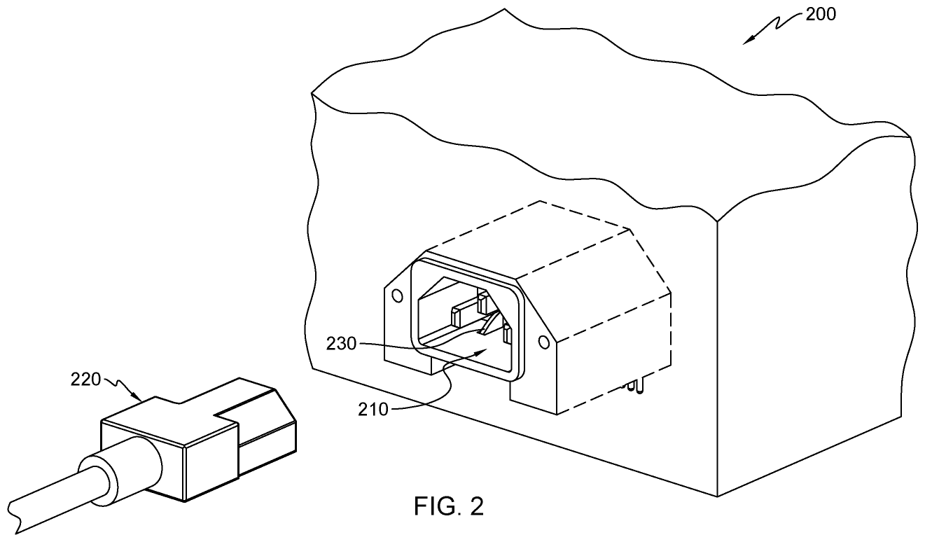

By way of example, FIG. 2 illustrates one embodiment of a network component 200 with a socket 210 configured, by way of example only, as a power socket. A cable includes a cable connector 220 or plug at one end, which is sized and configured to plug into socket 210 of network component 200. As illustrated, a portion of an actuator 230 is exposed within the opening of socket 210 so as to be engaged by cable connector 220 when the connector is being seated within socket 210.

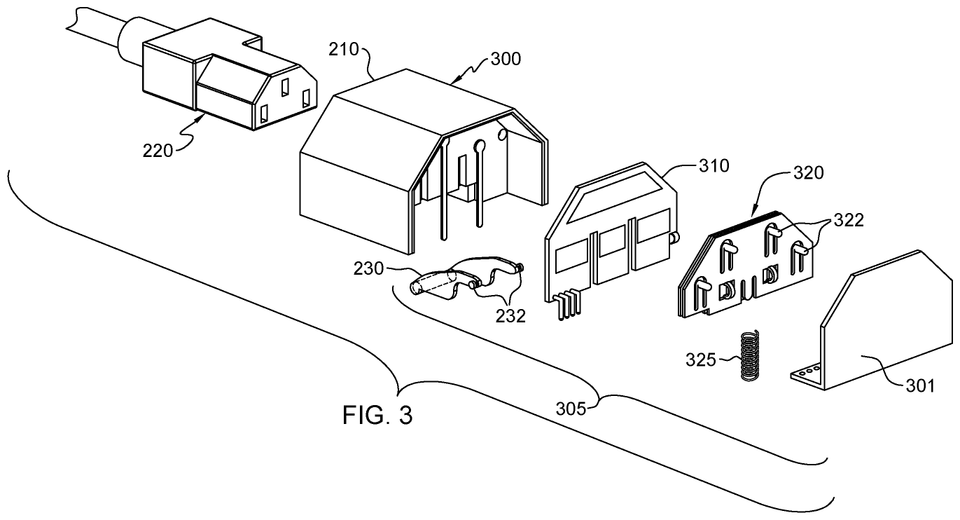

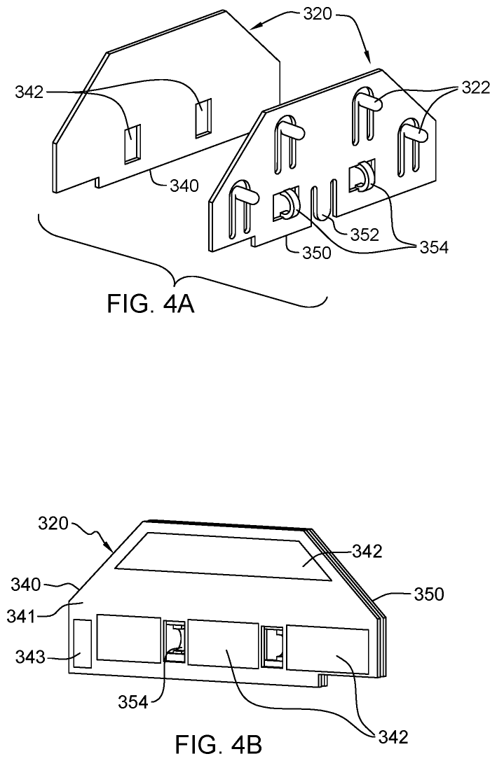

FIG. 3 is an exploded view of one embodiment of a receptacle 300 and an associated seating monitor 305, in accordance with one or more aspects of the present invention. In the embodiment depicted, socket 210, which receives cable connector 220, resides on one side of receptacle 300, and seating monitor 305 resides, in part, on the other side of the receptacle. In the embodiment illustrated, seating member 305 includes, in addition to actuator 230, a fixed member 310, such as a fixed card or fixed card assembly, and a slidable member 320, such as slidable card or slidable card assembly. Additionally, a spring-biasing mechanism 325 is provided to, in one or more embodiments, bias slidable member 320 in an upward direction relative to fixed member 310. Further, slidable member 320 includes biasing elements 322 which, when the monitor is assembled, contact a cover 301 of receptacle 300 to bias slidable member 320 towards fixed member 310. One embodiment of biasing elements 322 is depicted in greater detail in the enlarged, exploded view of FIG. 4A, which further illustrates one embodiment of slidable member 320.

As illustrated in FIG. 4A, slidable member 320 can include, in one or more embodiments, a slidable card 340 and a backing plate 350. In addition to biasing elements 322, backing plate 350 includes a receiving element 352 receiving the biasing spring 325 (FIG. 3), as well as U-shaped clips 354 which loosely hold a respective arm 232 (FIG. 3) of the actuator in position such that backing plate 350 is mechanically coupled to actuator 230 to slide, in one or more embodiments, vertically downward with displacement of actuator 230 within the socket due to seating of the cable connector within the socket. In the embodiment depicted, slidable card 340 includes elongate openings 342 to allow actuator arms 232 (FIG. 3) to extend through slidable card 340 for coupling to backing plate 350 via U-shaped clips 354.

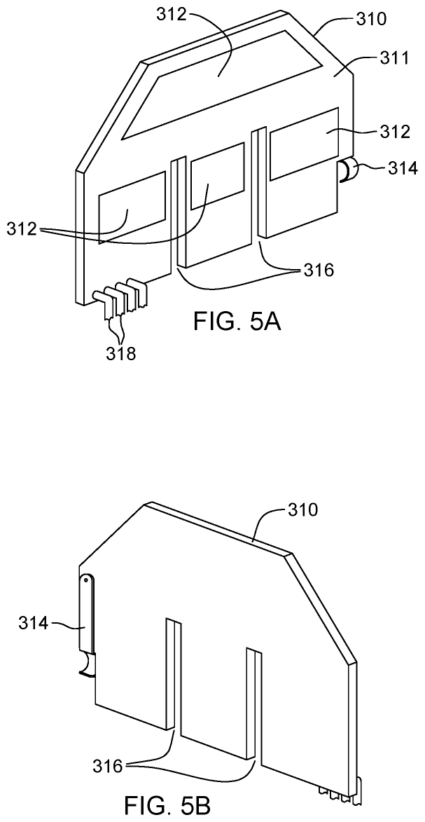

FIG. 4B depicts the assembled slidable member 320 of FIG. 4A, with slidable card 340 coupled to backing plate 350, for instance, adhesively coupled, in one or more embodiments. In FIG. 4B, a surface 341 is depicted which is opposite to a surface of the fixed member when operatively assembled within the receptacle. FIG. 5A depicts one embodiment of surface 311 of fixed member 310 which, as illustrated in FIG. 3, is facing or opposite to surface 341 of slidable card 340 of slidable member 320 when seating monitor 305 is operatively assembled within receptacle 300.

Referring collectively to FIGS. 4A-5B, surface 311 of fixed member 310 includes, by way of example, one or more first capacitor pads 312 facing, or in opposing relation to, one or more second capacitor pads 342 on surface 341 of slidable member 320. Any desired configuration and number of capacitor pads can be utilized as desired to implement a particular capacitive sensor between the fixed and slidable members. In one or more embodiments, the capacitor pads on surfaces 311 & 341 are conductive pads which are spaced apart by one or more offsets between fixed member 310 and slidable member 320. As shown, in one or more embodiments, slidable member 320 also includes a contact pad 343 which is electrically contacted by a spring contact 314 associated with fixed member 310.

In one or more embodiments, fixed member 310 can be sized larger than slidable member 320, which moves upward or downward based on displacement of the actuator within the socket. In the embodiment depicted, fixed member 310 also includes elongate slots 316 sized to allow actuator arms 232 (FIG. 3) to extend through fixed member 310 and move up or down relative to the fixed member. Electrical connectors or wires 318 are also provided from fixed member 310 to a circuit board (not shown) also associated with the receptacle, which can include, at least in part, a detector circuit which generates a signal representative of position of the slidable member relative to the fixed member, as explained herein.

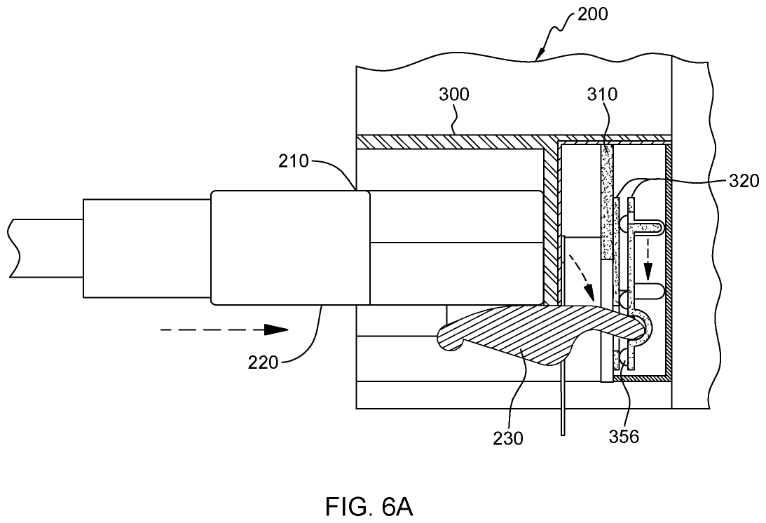

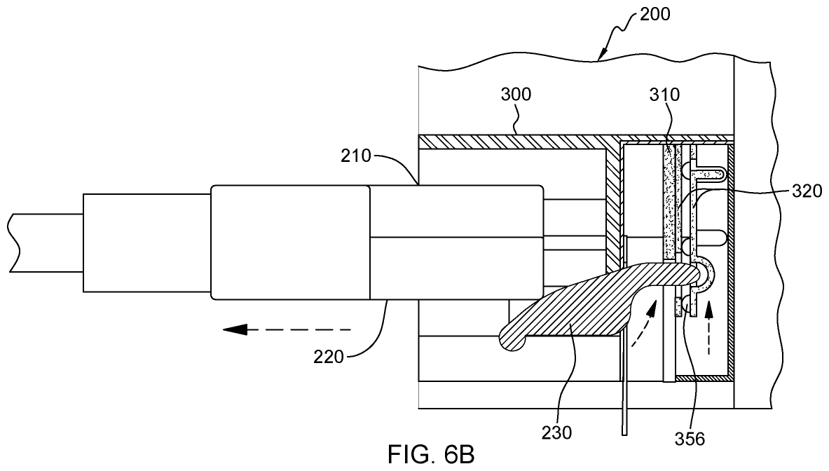

FIG. 6A depicts an example of seating of cable connector 220 within socket 210 of a receptacle 300 with an associated seating monitor as disclosed herein. As shown, with seating of cable connector 220 within socket 210, actuator 230 is physically engaged and moved in a downward direction (in the example shown). Actuator 230 is mechanically coupled to slidable member 320, which results in downward movement of slidable member 320 relative to fixed member 310. This change in position of the slidable member relative to the fixed member is monitored by the detector circuit through, in one or more embodiments, the capacitive sensor; that is, the capacitor pads and associated circuitry, associated with the fixed and slidable members. Those skilled in the art will note that the direction of movement of the actuator, and the slidable member, with seating of the connector are presented by way of example only.

FIG. 6B depicts the assembly of FIG. 6A, with cable connector 220 partially withdrawn from socket 210, resulting in change of position of actuator 230, and thus, change in position of slidable member 320 relative to fixed member 310, and which is detected by the detector circuit via the capacitive sensor(s) associated with the members. Advantageously, in one or more embodiments, capacitance of the capacitive sensor(s) varies, with seating or unseating of the connector. Based on the varying capacitance, a signal (or displacement data) can be generated by the detector circuit that is representative of the seating or partial unseating of the cable connector within the socket. As noted, in one or more embodiments, the displacement data can be forwarded a monitor system to, in part, provide an indication of the particular cable connector requiring operator attention to better seat the connector within the socket.

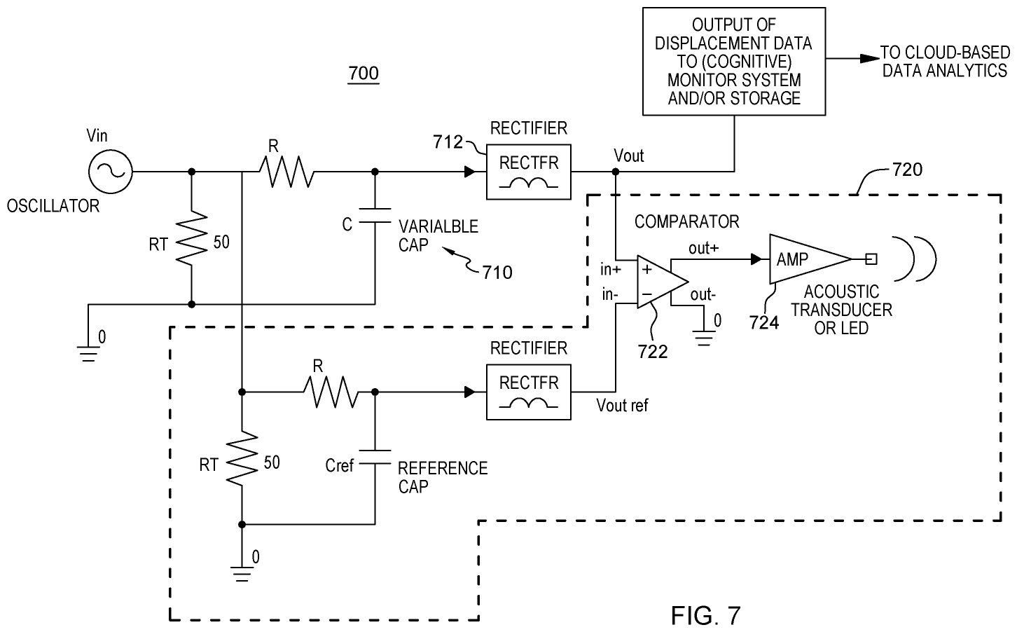

FIG. 7 depicts one embodiment of a detector circuit, generally denoted 700, in accordance with one or more aspects of the present invention. In one or more implementations, detector circuit 700 can be implemented on or in association with a circuit card, such as a printed circuit board, forming part of the seating monitor. By way of example, FIG. 7 depicts one example of a variable capacitance detector implementation, such as described above. In particular, a variable capacitor 710 forms part of the detector circuit, such as the variable capacitance obtained from a capacitive sensor associated with the fixed and slidable members of the seating monitor described above. As shown, in one or more embodiments, an oscillator applies an oscillating voltage Vin across resistors R, RT, to sense variable capacitance C, with the sensed signal being rectified 712 to provide a DC output voltage Vout. This voltage signal (Vout) can then be stored, and/or sent to a monitor system 714. Based on mechanical displacement of the slidable member relative to the fixed member, and more particularly, based on displacement of capacitor pads on the slidable member relative to capacitor pads on the fixed member, the output voltage Vout changes. By way of example, the output voltage Vout can be determined as:

$$Vout = \frac{{Xc}^{2}}{\sqrt{{R}^{2} + {Xc}^{2}}} Vin \qquad ( 1 )$$

where:

Xc=the capacitive reactance;

R=a resistance value selected for a particular implementation; and

Vin=oscillator input voltage.

Further, the variable capacitance C can be expressed as:

$$C = \frac{\sqrt{{( \frac{Vin}{Vout} )}^{2} - 1}}{2 π fR} \qquad ( 2 )$$

where:

ƒ=oscillator frequency.

As depicted in FIG. 7, a reference circuit 720 can also be provided as part of the detector circuit to facilitate identifying locally when, for instance, a cable connector is fully seated within the socket, and/or unseated, and to provide, based thereon, an audible or visual signal. In the embodiment depicted, a reference capacitance Cref, such as in the range of 25 pF to 150 pF, receives the oscillating input voltage Vin signal across resistors RT, and R, with the output being rectified to produce a Vout—ref signal, that is fed to a comparator 722, along with the output voltage Vout signal ascertained from the variable capacitance 710. As noted, the amplitude of voltage Vout is directly proportional to the capacitance value, and so, after rectification to convert to DC, comparison of the two voltages triggers a high output if C>Cref. In an alternative embodiment, if a high output for C<Cref is desired, then the connections to the comparator can be reversed. As illustrated, in one or more embodiments, the output of comparator 722 can be amplified 724 to drive an acoustic transducer and/or one or more light-emitting diodes to provide an audible and/or visual indication of seating, partial seating, or unseating of a cable connector within the socket.

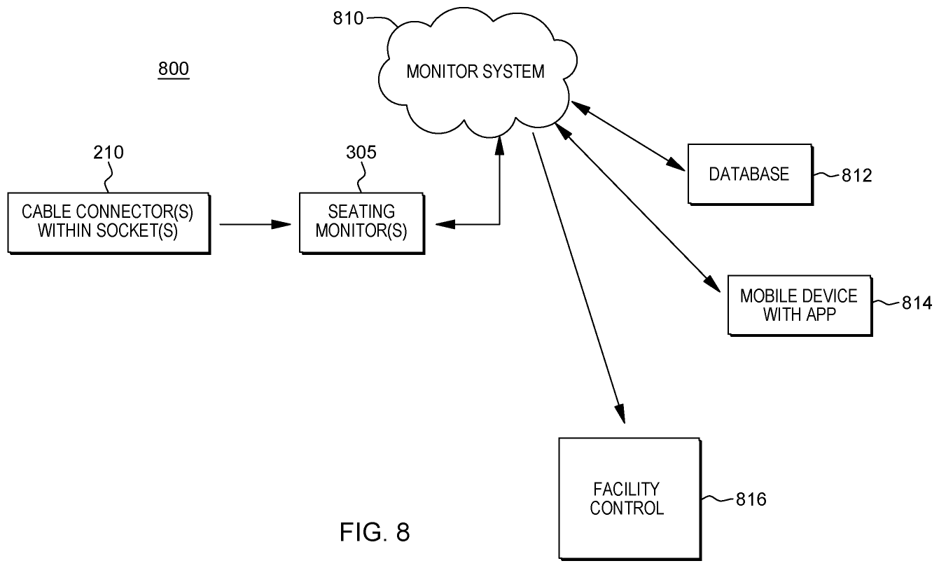

By way of example, FIG. 8 depicts one embodiment of a system 800 for monitoring signals produced by multiple seating monitors 305 of a network. As noted, seating monitors 305 provide signals based on the seating and/or unseating of cable connectors 210 within the associated sockets of the component, device, subsystem, system, network, etc. The signals can be forwarded from seating monitors 305 via a communication network to a remote server, such as a cloud-based (cognitive) monitor system 810. The communication network employed can be any medium used to provide communication links between various devices and computers connected together within a processing environment. For instance, the communication network can include connections, such as wires, wireless communication links, fiber optic links, etc. In one or more embodiments, the network can utilize the Internet, or a different type of network, such as an intranet, a local area network (LAN), a wide area network (WAN), a wireless network, etc.

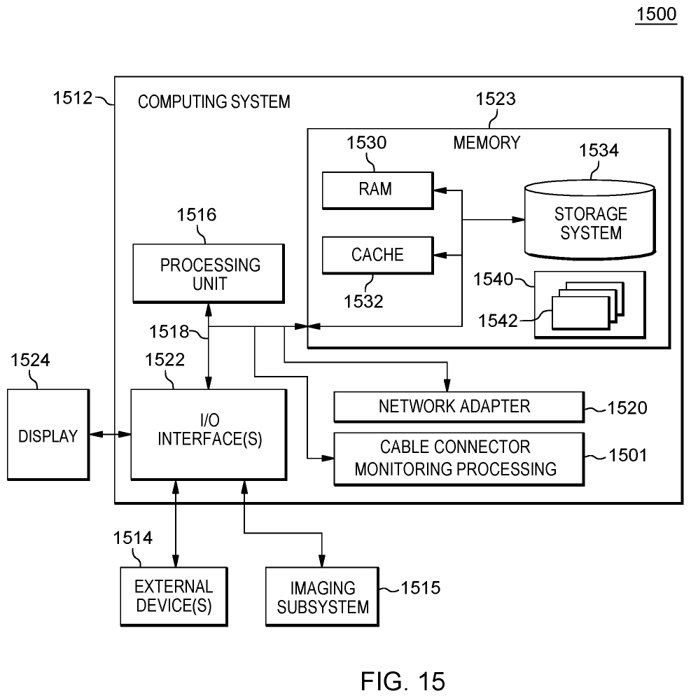

The remote server, such as a cloud-based monitoring system 810, can be implemented as any of a variety of computer systems, such as those described below with reference to FIGS. 15-17. Also, note in this regard that the illustrative aspects described herein can be applied to any of a variety of computing environments. In the example of FIG. 8, the monitor system 810 can be a backend or cloud-based server which can include a database 812 for storing displacement data from the seating monitors 305, as well as one or more facilities for signaling, for instance, a mobile device with an appropriate monitor application 814, and/or a control system at a particular location, such as a data center 816, to initiate an operator checking seating of a particular cable connection within the network. A variety of monitoring systems can be implemented to process the received displacement data from the seating monitors 305. In one or more embodiments, the monitoring system can be a cognitive system, such as a cognitive computing system. For instance, the monitoring system can be implemented as program code executing on one or more processors, which uses existing cognitive analysis tools or agents to process the displacement data received from the seating monitors. In one or more embodiments, aspects of the present invention can utilize IBM Watson® as the cognitive agent. IBM Watson® is a product of International Business Machines Corporation, and is a registered trademark of International Business Machines Corporation, Armonk, N.Y.(USA). In one or more embodiments, the program code can interface with IBM Watson® APIs to perform a cognitive analysis of obtained data. For instance, the analytics could evaluate trends in the displacement data, such as a cable connector becoming gradually unseated, as well as service history for a particular cable connector or component within the network, displacement of a cable connector over time, and generate predictive actions, such as a predictive service call or a predictive signal, based on identified trends in the displacement data.

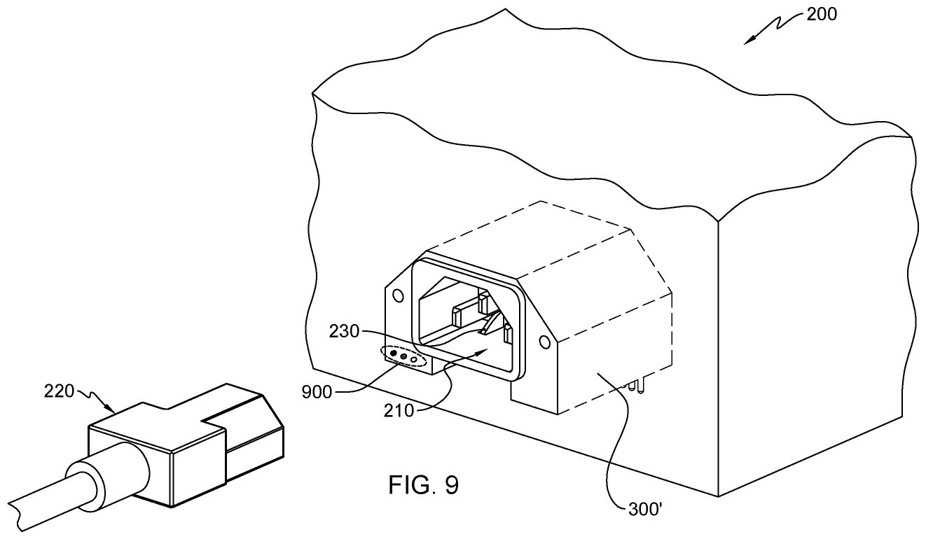

As a further example, FIG. 9 depicts another embodiment of a network component 200 with a receptacle 300′ which includes a socket 210 into which a cable connector 220 is to be operatively seated. As described above in connection with FIG. 2, a portion of actuator 230 is exposed within the opening of socket 210 so as to be engaged by cable connector 220 when being seated into socket 210. In the embodiment of FIG. 9, multiple light emitting diodes 900 are associated with receptacle 300′ to provide visual feedback to an operator on the state of seating or unseating of cable connector 220 within socket 210, as described herein.

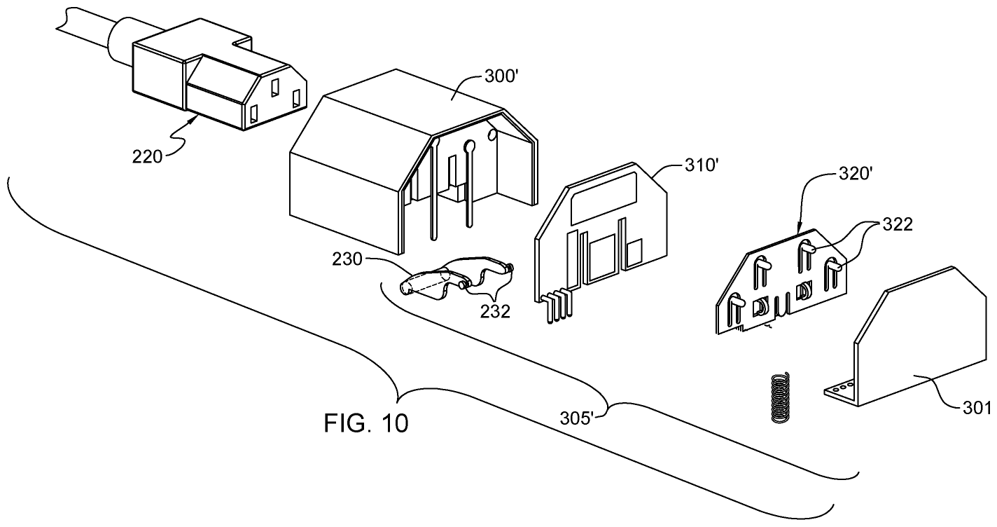

FIG. 10 is an exploded view of one embodiment of receptacle 300′ and an associated seating monitor 305′, in accordance with one or more aspects of the present invention. In the embodiment depicted, the socket which receives cable connector 220, resides at one side of receptacle 300′, and seating monitor 305′ resides, in part, on the other side of the receptacle. As shown, seating monitor 305′ in this embodiment includes actuator 230, a fixed member 310′, such as a fixed card or fixed card assembly, and a slidable member 320′, such as a slidable card or slidable card assembly. Additionally, spring biasing mechanism 325 is provided to, in one or more embodiments, bias slidable member 320′ in an upward direction relative to fixed member 310′. Further, slidable member 320′ includes biasing elements 322 which, when the seating monitor is assembled, contact cover 301 of receptacle 300′ to bias slidable member 320′ towards fixed member 310′.

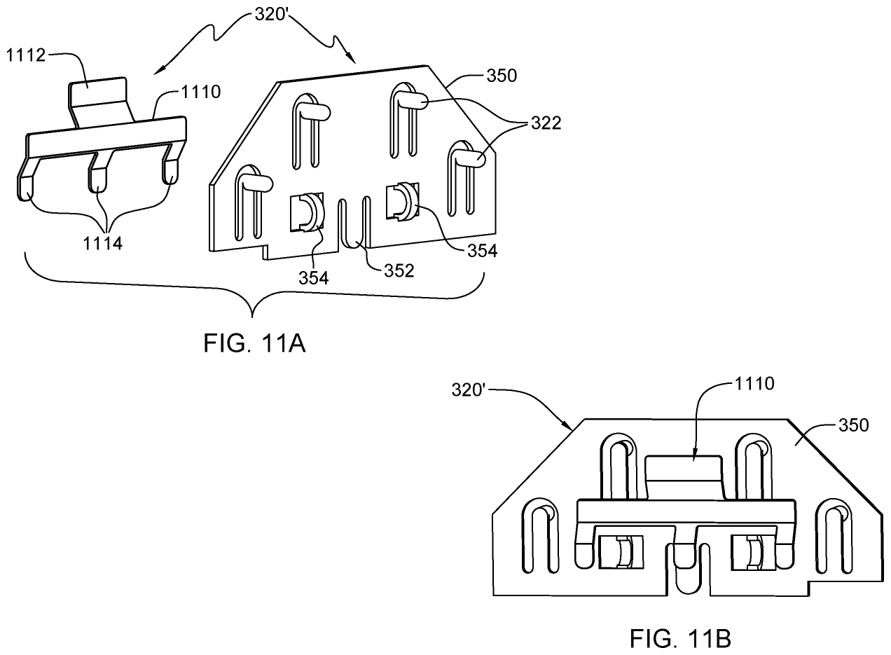

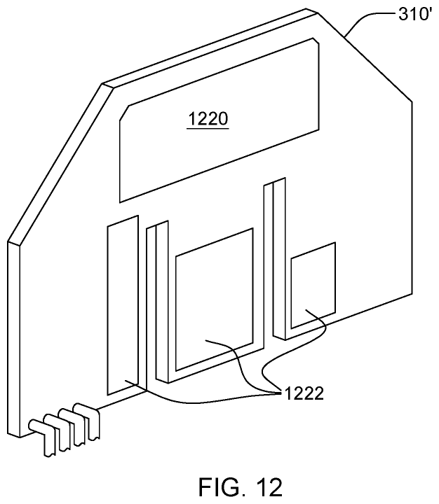

FIGS. 11A & 11B depict in greater detail one embodiment of slidable member 320′. As depicted, slidable member 320′ includes, in the embodiment shown, backing plate 350 and a conductive spring contact 1110 associated with backing plate 350. As with the embodiment described above, backing plate 350 further includes receiving element 352 which receives biasing spring 325 (FIG. 10), as well as U-shaped clips 354 which loosely hold a respective arm 232 (FIG. 10) of the actuator such that backing plate 350 is mechanically coupled to the actuator to slide, in one or more embodiments, vertically downward with displacement of actuator 230 (FIGS. 9 & 10) within the socket due to seating of the cable connector within the socket. In the embodiment depicted, conductive spring contact 1110 includes contact arms 1112 & 1114 which are positioned and sized to electrically contact respective contact pads 1220, 1222 on fixed member 310′, one embodiment of which is depicted in FIG. 12.

As depicted in FIGS. 10-12, the conductive spring contact (or multi-contact slider) makes electrical connection with different contact pads 1222 depending on the amount of displacement of the actuator, and thus, the amount of downward sliding of the slidable member 320′. Note that any number of differently positioned and/or sized contact pads and conductive arms of the conductive spring contact can be provided to sense multiple different positions of the cable connector within the socket, as desired.

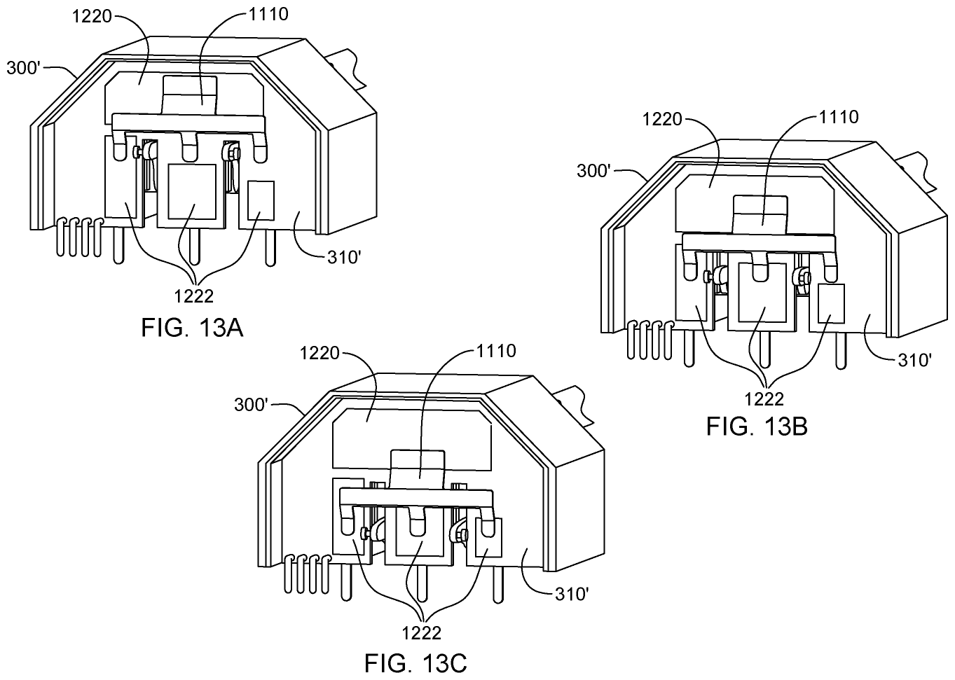

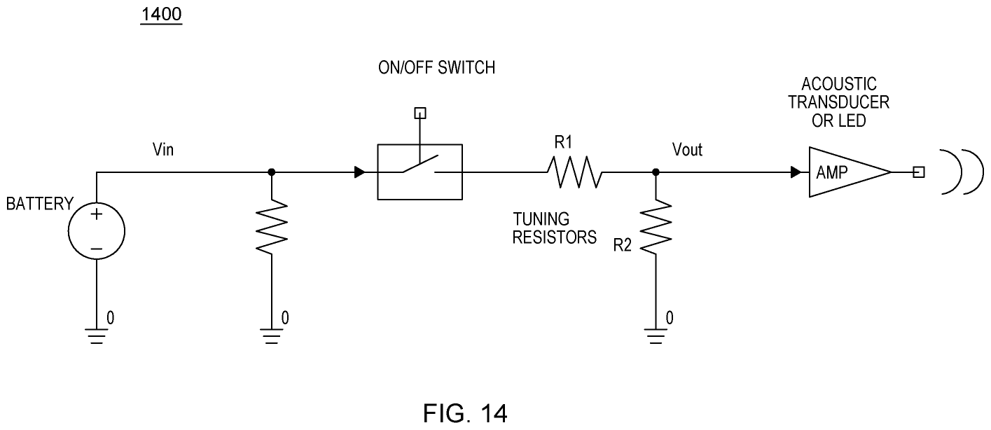

FIGS. 13A-13C depict by way of example different positions of conductive spring contact 1110 relative to contact pads 1222 of fixed member 310′. As illustrated, depending on the position of conductive spring contact 1110, different electrical connections are made bridging, for instance, common contact pad 1220 and one or more of the differently sized contact pads 1222. In one or more embodiments, the detector circuit is configured to ascertain the different positions of conductive spring contact 1110 relative to contact pads 1220, 1222, and thus, ascertain one or more different positions of the cable connector within the socket, as desired for a particular seating monitor implementation. In FIG. 13A, the cable connector is unseated from the socket, while in FIG. 13B, the cable connector has been partially seated into the socket, and in FIG. 13C, the cable connector is assumed to have been fully seated within the socket.

By way of example, FIG. 14 depicts a further embodiment of a detector circuit 1400 which can be used in association with an apparatus for monitoring seating of a cable connector within a socket as depicted in FIGS. 9-13C. Referring collectively to FIGS. 9-14, multiple detector circuits 1400 such as depicted in FIG. 14 can be employed with the seating monitor to, for instance, detect a particular electrical connection between common contact pad 1220 and a particular contact pad 1222, with each potential contact being represented as an on/off switch in the circuit. When the switch is closed, an output voltage Vout is provided, which is used by an amplifier to drive an acoustic transducer and/or one or more light-emitting diodes, such as light-emitting diodes 900 of FIG. 9. Thus, in the three contact pad 1222 embodiment of FIGS. 9-13C, an output voltage Vout could be generated based on whether the cable connector is seated, partially seated, or unseated.

Those skilled in the art will note from the above description that provided herein are apparatuses and methods to monitor directly the magnitude of seating and/or unseating of a cable connector within a socket. The apparatus is implemented, at least in part, at the receptacle side of the connection. This location means that power is available to continuously conduct, for instance, system-level monitoring and storing of displacement or unseating information to determine one or more actions to be performed. The apparatus can use, in one or more embodiments, capacitive sensors and/or electrical contact sensors to detect relative displacement and provided an appropriate warning when a relative displacement or unseating is greater than an allowable value, as well as store displacement information for subsequent action. Advantageously, the capacitor sensor directly measures the amount of connector displacement. While the embodiments depicted and described herein are illustrated as power connections, it will be understood by those skilled in the art that the apparatuses and methods disclosed are applicable to any type of cable connector-to-socket connection.

Exemplary embodiments of a computing environment which may implement one or more aspects of the present invention are described below with reference to FIGS. 15-17.

By way of further example, FIG. 15 depicts one embodiment of a computing environment 1500, which includes a computing system 1512. Examples of well-known computing systems, environments, and/or configurations that may be suitable for use with computer system 1512 include, but are not limited to, a server, a desktop computer, a workstation, a mobile device, such as a wireless computer, a handheld or laptop computer or device, a mobile phone, a programmable consumer electronic device, a tablet, a personal digital assistant (PDA), or the like.

Computing system 1512 can be described in the general context of computer system-executable instructions, such as program modules, being executed by a computer system. Generally, program modules can include routines, programs, objects, components, logic, data structures, and so on that perform particular tasks or implement particular abstract data types.

As depicted in FIG. 15, computing system 1512, is shown in the form of a general-purpose computing device. The components of computing system 1512 can include, but are not limited to, one or more processors or processing units 1516, a system memory 1523, and a bus 1518 that couples various system components including system memory 1523 to processor 1516.

In one embodiment, processor 1516 may be based on the z/Architecture® offered by International Business Machines Corporation, or other architectures offered by International Business Machines Corporation or other companies. z/Architecture® is a registered trademark of International Business Machines Corporation, Armonk, N.Y., USA. One embodiment of the z/Architecture® is described in “z/Architecture Principles of Operation,” IBM® Publication No.SA22-7832-11, 12^{th} edition, September 2017, which is hereby incorporated herein by reference in its entirety.

In other examples, it may be based on other architectures, such as the Power Architecture offered by International Business Machines Corporation. One embodiment of the Power Architecture is described in “Power ISA™ Version 2.07B,” International Business Machines Corporation, Apr. 9, 2015, which is hereby incorporated herein by reference in its entirety. POWER ARCHITECTURE is a registered trademark of International Business Machines Corporation, Armonk, N.Y., USA. Other names used herein may be registered trademarks, trademarks, or product names of International Business Machines Corporation or other companies.

Bus 1518 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computing system 1512 can include a variety of computer system readable media. Such media can be any available media that is accessible by computing system 1512, and it includes both volatile and non-volatile media, removable and non-removable media.

System memory 1523 can include computer system readable media in the form of volatile memory, such as random access memory (RAM) 1530 and/or cache memory 1532. Computing system 1512 may further include other removable/non-removable, volatile/non-volatile computer system storage media. By way of example only, storage system 1534 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media could be provided. In such instances, each can be connected to bus 1518 by one or more data media interfaces. As described below, memory 1523 can include at least one program product having a set (e.g., at least one) of program modules that are configured to carry out the functions of embodiments of the invention.

Program/utility 1540, having a set (at least one) of program modules 1542, can be stored in memory 1523 by way of example, and not limitation, as well as an operating system, one or more application programs, other program modules, and program data. Each of the operating system, one or more application programs, other program modules, and program data or some combination thereof, can include an implementation of a networking environment. Program modules 1542 generally carry out the functions and/or methodologies of embodiments of the invention as described herein. Alternatively, a separate cable connector monitoring system, module, logic, etc., 1501 may be provided within computing environment 1512.

Computing system 1512 can also communicate with one or more external devices 1514 such as an imaging subsystem 1515, a keyboard, a pointing device, a display 1524, etc.; one or more devices that enable a user to interact with computing system 1512; and/or any devices (e.g., network card, modem, etc.) that enable computing system 1512 to communicate with one or more other computing devices. Such communication can occur via Input/Output (I/O) interfaces 1522. Still yet, computing system 1512 can communicate with one or more networks such as a local area network (LAN), a general wide area network (WAN), and/or a public network (e.g., the Internet) via network adapter 1520. As depicted, network adapter 1520 communicates with the other components of computing system, 1512, via bus 1518. It should be understood that although not shown, other hardware and/or software components could be used in conjunction with computing system 1512. Examples, include, but are not limited to: microcode, device drivers, redundant processing units, external disk drive arrays, RAID systems, tape drives, and data archival storage systems, etc.

One or more aspects may relate to or use cloud computing.

It is understood in advance that although this disclosure includes a detailed description on cloud computing, implementation of certain teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based email). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

A cloud computing node may include a computer system/server, such as the one depicted in FIG. 15. Computing system 1512 of FIG. 15 can be practiced in distributed cloud computing environments where tasks are performed by remote processing devices that are linked through a communications network. In a distributed cloud computing environment, program modules may be located in both local and remote computer system storage media including memory storage devices. Computing system 1512 is capable of being implemented and/or performing any of the functionality set forth hereinabove.

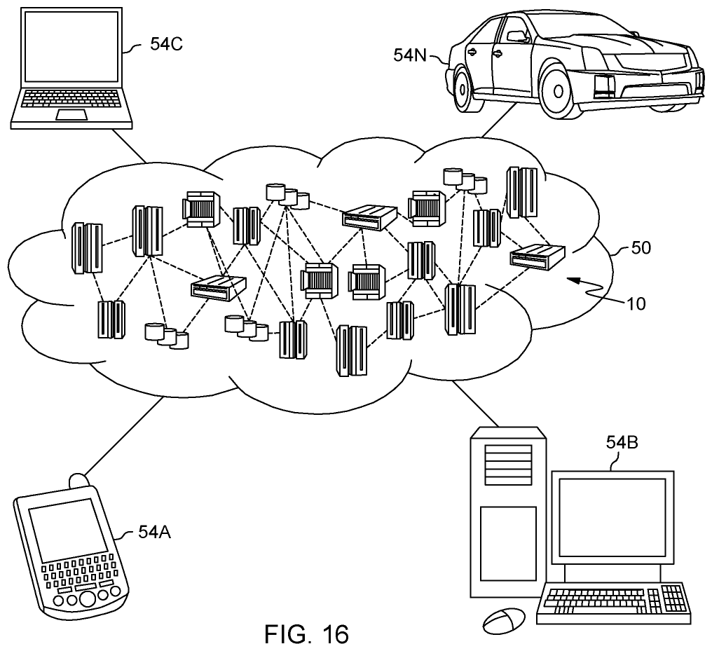

Referring now to FIG. 16, illustrative cloud computing environment 50 is depicted. As shown, cloud computing environment 50 comprises one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They can be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 16 are intended to be illustrative only and that computing nodes 10 and cloud computing environment 50 can communicate with any type of computerized device over any type of network and/or network addressable connection (e.g., using a web browser).

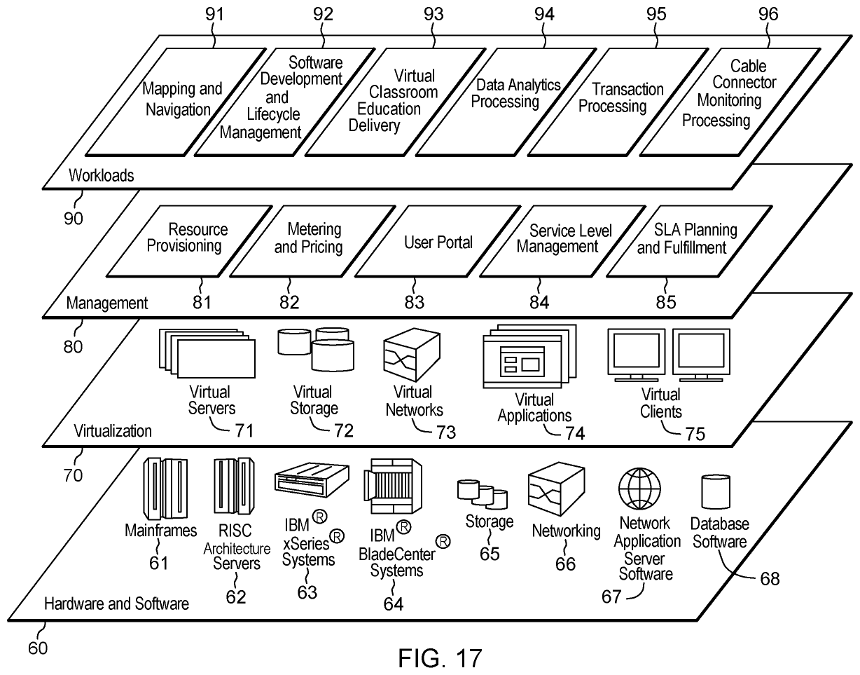

Referring to FIG. 17, a set of functional abstraction layers provided by cloud computing environment 50 (FIG. 16) is shown. It should be understood in advance that the components, layers, and functions shown in FIG. 17 are intended to be illustrative only and embodiments of the invention are not limited thereto. As depicted, the following layers and corresponding functions are provided:

Hardware and software layer 60 includes hardware and software components. Examples of hardware components include mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may comprise application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and cable connector monitoring processing 96.

The descriptions of the various embodiments of the present invention have been presented for purposes of illustration, but are not intended to be exhaustive or limited to the embodiments disclosed. Many modifications and variations will be apparent to those of ordinary skills in the art without departing from the scope and spirit of the described embodiments. The terminology used herein was chosen to best explain the principles of the embodiments, the practical application or technical improvement over technologies found in the marketplace, or to enable others of ordinary skills in the art to understand the embodiments disclosed herein.

The present invention can be an apparatus, system, method, and/or computer program product at any possible technical detail level of integration. The computer program product can include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

In addition to the above, one or more aspects can be provided, offered, deployed, managed, serviced, etc. by a service provider who offers management of customer environments. For instance, the service provider can create, maintain, support, etc. computer code and/or a computer infrastructure that performs one or more aspects for one or more customers. In return, the service provider can receive payment from the customer under a subscription and/or fee agreement, as examples. Additionally or alternatively, the service provider may receive payment from the sale of advertising content to one or more third parties.

In one aspect, an application may be deployed for performing one or more embodiments. As one example, the deploying of an application comprises providing computer infrastructure operable to perform one or more embodiments.

As a further aspect, a computing infrastructure can be deployed comprising integrating computer readable code into a computing system, in which the code in combination with the computing system is capable of performing one or more embodiments.

As yet a further aspect, a process for integrating computing infrastructure comprising integrating computer readable code into a computer system can be provided. The computer system comprises a computer readable medium, in which the computer medium comprises one or more embodiments. The code in combination with the computer system is capable of performing one or more embodiments.

Although various embodiments are described above, these are only examples. For example, computing environments of other architectures can be used to incorporate and use one or more embodiments. Further, different instructions, instruction formats, instruction fields and/or instruction values may be used. Many variations are possible.

Further, other types of computing environments can benefit and be used. As an example, a data processing system suitable for storing and/or executing program code is usable that includes at least two processors coupled directly or indirectly to memory elements through a system bus. The memory elements include, for instance, local memory employed during actual execution of the program code, bulk storage, and cache memory which provide temporary storage of at least some program code in order to reduce the number of times code must be retrieved from bulk storage during execution.

Input/Output or I/O devices (including, but not limited to, keyboards, displays, pointing devices, DASD, tape, CDs, DVDs, thumb drives and other memory media, etc.) can be coupled to the system either directly or through intervening I/O controllers. Network adapters may also be coupled to the system to enable the data processing system to become coupled to other data processing systems or remote printers or storage devices through intervening private or public networks. Modems, cable modems, and Ethernet cards are just a few of the available types of network adapters.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. An apparatus for monitoring seating of a cable connector within a socket, the apparatus comprising:
a seating monitor associated with the socket, the seating monitor comprising:
an actuator partially exposed within the socket, the actuator being engaged by the cable connector and physically moved from a cable unplugged position to a cable plugged position with seating of the cable connector within the socket; and
a detector to monitor seating of the cable connector within the socket based on position of the actuator, the detector comprising:
a fixed member fixedly positioned within the detector;
a slidable member slidable relative to the fixed member, the slidable member being coupled to the actuator to slide with movement of the actuator between the cable unplugged position and the cable plugged position; and
a detector circuit to generate a signal representative of position of the slidable member relative to the fixed member, and thus representative of position of the cable connector within the socket.

2. The apparatus of claim 1, wherein the detector circuit comprises:
a capacitive sensor associated with the fixed member and the slidable member to sense position of the slidable member relative to the fixed member; and
wherein the detector circuit generates actuator displacement data from, at least in part, the capacitive sensor, where capacitance sensed by the capacitive sensor varies with position of the slidable member relative to the fixed member.

3. The apparatus of claim 2, wherein the capacitive sensor comprises:
one or more first capacitor pads disposed on a first surface of the fixed member; and
one or more second capacitor pads disposed on a second surface of the slidable member, the first surface and the second surface being opposite facing surfaces.

4. The apparatus of claim 3, wherein the fixed member comprises a fixed card and the slidable member comprises a slidable card, and wherein the slidable card is biased towards the fixed card, and is spaced therefrom via one or more offsets.

5. The apparatus of claim 1, wherein the detector circuit comprises:
an electrical contact sensor associated with the fixed member and the slidable member to sense position of the slidable member relative to the fixed member; and
wherein the detector circuit generates actuator displacement data from, at least in part, the electrical contact sensor, where a signal produced by the detector circuit varies with position of the slidable member relative to the fixed member.

6. The apparatus of claim 5, wherein the electrical contact sensor includes multiple contact pads associated with one of the fixed member and the slidable member, and a conductive spring contact associated with the other of the fixed member and the slidable member, the conductive spring contact making electrical contact with one or more of the multiple contact pads with changing position of the slidable member relative to the fixed member.

7. The apparatus of claim 6, wherein the fixed member comprises a fixed card and the slidable member comprises a slidable card, and the multiple contact pads are disposed on a first surface of the fixed card and the conductive spring contact extends from a second surface of the slidable card, the first surface and the second surface being opposing facing surfaces.

8. The apparatus of claim 1, wherein the slidable member is spring-biased in a first direction and the slidable member moves in a second direction, opposite to the first direction, with movement of the actuator from the cable unplugged position to the cable plugged position.

9. The apparatus of claim 1, wherein the detector circuit generates at least one signal from the group consisting of an acoustic signal and a visual signal based on the signal generated by the detector circuit exceeding a set reference signal.

10. The apparatus of claim 1, further comprising a monitor system to monitor over time seating of the cable connector in the socket based on the signal generated by the detect circuit, and upon detecting an at least partial unseating of the cable connector from the socket, to provide an indication that the cable connector should be re-seated within the socket.

11. The apparatus of claim 1, wherein the seating monitor resides, in part, within a receptacle also containing the socket.

12. Apparatus for monitoring seating of cable connectors within network sockets, the apparatus comprising:
seating monitors associated with the network sockets, each seating monitor of the seating monitors being associated with a respective network socket and comprising:
an actuator partially exposed within the network socket, the actuator being engaged by a cable connector and physically moved from a cable unplugged position to a cable plugged position with seating of the cable connector within the network socket; and
a detector to monitor seating of the cable connector within the network socket based on position of the actuator, the detector comprising:
a fixed member fixedly positioned within the detector;
a slidable member slidable relative to the fixed member, the slidable member being coupled to the actuator to slide with movement of the actuator between the cable unplugged position and the cable plugged position; and
a detector circuit to generate a signal representative of position of the slidable member relative to the fixed member, and thus representative of position of the cable connector within the socket; and
a monitor system coupled to the seating monitors to monitor over time seating of the cable connectors within the network sockets based on the signals generated by the detector circuits of the seating monitors.

13. The apparatus of claim 12, where the monitor system, upon detecting an unseating of a cable connector from a network socket of the network sockets, provides an indication that the cable connector needs to be re-seated within the network socket, the identification including an identification of the cable connector unseated from the respective network socket.

14. The apparatus of claim 12, wherein the detector circuit comprises:
a capacitive sensor associated with the fixed member and the slidable member to sense position of the slidable member relative to the fixed member; and
wherein the detector circuit generates actuator displacement data from, at least in part, the capacitive sensor, where capacitance sensed by the capacitive sensor varies with position of the slidable member relative to the fixed member.

15. The apparatus of claim 14, wherein the capacitive sensor comprises:
one or more first capacitor pads disposed on a first surface of the fixed member; and
one or more second capacitor pads disposed on a second surface of the slidable member, the first surface and the second surface being opposite facing surfaces.

16. The apparatus of claim 15, wherein the fixed member comprises a fixed card and the slidable member comprises a slidable card, and wherein the slidable card is biased towards the fixed card, and is spaced therefrom via one or more offsets.

17. The apparatus of claim 12, wherein the detector circuit comprises:
an electrical contact sensor associated with the fixed member and the slidable member to sense position of the slidable member relative to the fixed member; and
wherein the detector circuit generates actuator displacement data from, at least in part, the electrical contact sensor, where a signal produced by the detector circuit varies with position of the slidable member relative to the fixed member.

18. The apparatus of claim 17, wherein the electrical contact sensor includes multiple contact pads associated with one of the fixed member and the slidable member, and a conductive spring contact associated with the other of the fixed member and the slidable member, the conductive spring contact making electrical contact with one or more of the multiple contact pads with changing position of the slidable member relative to the fixed member.

19. The apparatus of claim 18, wherein the fixed member comprises a fixed card and the slidable member comprises a slidable card, and the multiple contact pads are disposed on a first surface of the fixed card and the conductive spring contact extends from a second surface of the slidable card, the first surface and the second surface being opposite facing surfaces.

20. A method of fabricating an apparatus to monitor seating of a cable connector within a socket, the method comprising:
associating a seating monitor with the socket, the associating of the seating monitor including:
providing an actuator partially exposed within the socket, the actuator being engaged by the cable connector and physically moved from a cable unplugged position to a cable plugged position with seating of the cable connector within the socket; and
providing a detector to monitor seating of the cable connector within the socket based on position of the actuator, the detector comprising:
a fixed member fixedly positioned within the detector;
a slidable member slidable relative to the fixed member, the slidable member being coupled to the actuator to slide with movement of the actuator between the cable unplugged position and the cable plugged position; and
a detector circuit to generate a signal representative of position of the slidable member relative to the fixed member, and thus representative of position of the cable connector within the socket.
